(19) United States
(12) Patent Application Publication
(10) Pub. No.: US 2020/0412982 A1
(43) Pub. Date: Dec. 31, 2020

(54) LAMINATED IMAGE PICKUP DEVICE, IMAGE PICKUP APPARATUS, IMAGE PICKUP METHOD, AND RECORDING MEDIUM RECORDED WITH IMAGE PICKUP PROGRAM

(71) Applicant: Olympus Corporation, Tokyo (JP)

(72) Inventors: Kazuhiro HANEDA, Tokyo (JP); Sumio KAWAI, Tokyo (JP); Masaomi TOMIZAWA, Tokyo (JP); Kazuhiko OSA, Tokyo (JP); Osamu NONAKA, Sagamihara-shi (JP)

(21) Appl. No.: 16/913,922

(22) Filed: Jun. 26, 2020

(30) Foreign Application Priority Data
Jun. 27, 2019 (JP) 2019-120158

(51) Int. Cl. H04N 5/341; H04N 5/953; H04N 5/3745; H01L 27/146

(52) U.S. Cl. CPC H04N 5/341; H01L 27/14621; H04N 5/37455; H04N 5/953

(57) ABSTRACT

A laminated image pickup device includes: a sensor including a plurality of pixels configured on a sensor substrate and configured to continuously acquire image data at a predetermined frame rate; and a processor. The processor is provided on a substrate other than the sensor substrate, and is configured to perform, based on the image data, region judgement processing of obtaining a priority region including some pixels of the plurality of pixels and to obtain outputs of the some pixels included in the priority region at a higher frame rate than the predetermined frame rate.

### CROSS REFERENCE TO RELATED APPLICATION

This application claims the benefit of Japanese Application No. 2019-120158 filed in Japan on Jun. 27, 2019, the contents of which are incorporated herein by this reference.

### BACKGROUND OF THE INVENTION

### 1. Field of the Invention

The present invention relates to a laminated image pickup device, an image pickup apparatus, an image pickup method, and a recording medium recorded with an image pickup program which enable high-speed reading.

### 2. Description of the Related Art

In recent years, portable devices (photographing devices) with a photographing function such as digital cameras have become widespread. As an image pickup device used in these types of photographing devices, a laminated image pickup device has been developed. The laminated image pickup device has a laminated structure of a layer in which a pixel unit (sensor unit) having pixels for image pickup is formed (hereinafter, referred to as a sensor layer) and a layer in which a signal processing circuit is formed (hereinafter, referred to as a signal processing layer). When the laminated structure of the sensor layer and the signal processing layer is adopted, a size of the sensor can be reduced and the number of pixels can be increased compared with an image pickup device in which the sensor unit and the signal processing circuit (peripheral circuit) are formed in the same layer.

Further, since a circuit space of the signal processing layer has a margin, a signal processing circuit having a relatively large scale can be mounted, and a multifunctional image pickup device can be configured. In addition, the sensor layer and the signal processing layer may be manufactured by separate processes, and a manufacturing process specialized for high image quality can be adopted.

As an image pickup device with high image quality, an apparatus is proposed in Japanese Patent Application Laid-Open Publication No. 2016-219977. According to the proposal, an image pickup device includes a pixel (color pixel) in which R, G, and B color filters are arranged and a pixel (W pixel) in which the color filters are not arranged, and weighting of inter-frame differential processing of the W pixel is changed based on inter-frame differential of the color pixel, thereby color noise is reduced, a color afterimage is suppressed, and image quality of a movie is increased.

In order to increase the image quality, the image pickup device tends to increase in the number of pixels and a frame rate, and a processing amount required for image processing is increasing. In addition, a processing amount of the signal processing circuit for high image quality processing also tends to increase.

However, the image pickup apparatus needs to process the image pickup signal in real time, and as a result, the frame rate may not be desirably increased.

The present invention is to provide a laminated image pickup device, an image pickup apparatus, an image pickup method, and a recording medium recorded with an image pickup program capable of predicting a pixel region to be read from a pixel and limiting a read region to enable reading at a high-speed frame rate.

### SUMMARY OF THE INVENTION

A laminated image pickup device according to an aspect of the present invention includes: a sensor including a plurality of pixels configured on a sensor substrate and configured to continuously acquire image data at a predetermined frame rate; and a processor, wherein the processor is provided on a substrate other than the sensor substrate, and is configured to perform, based on the image data, region judgement processing of obtaining a priority region including some pixels of the plurality of pixels, and to obtain outputs of the some pixels included in the priority region at a higher frame rate than the predetermined frame rate.

An image pickup apparatus according to an aspect of the present invention includes the laminated image pickup device and a controller configured to control the laminated image pickup device.

An image pickup apparatus according to an aspect of the present invention includes: a laminated image pickup device including a sensor including a plurality of pixels configured on a sensor substrate and configured to continuously acquire image data at a predetermined frame rate; a processor; and a memory, the processor being provided on a substrate other than the sensor substrate, and being configured to perform, based on the image data, region judgment processing of obtaining a priority region including some pixels of the plurality of pixels, and to obtain outputs of the some pixels included in the priority region at a higher frame rate than the predetermined frame rate, the memory being configured to temporarily store image data based on the outputs of the plurality of pixels, the processor including an inference engine using an inference model to which the image data temporarily stored in the memory is inputted to infer the region including the image part of the moving object in the inputted image data, wherein a region including an image part of a moving object in the image data temporarily stored in the memory is set as the priority region; and a controller configured to control the laminated image pickup device, wherein the processor updates the inference model.

An image pickup method according to an aspect of the present invention includes: continuously acquiring image data at a predetermined frame rate with a sensor provided on a laminated sensor and including a plurality of pixels; obtaining, in a circuit on a different layer from the sensor, a priority region including some pixels of the plurality of pixels, based on the image data; and obtaining outputs of the some pixels included in the priority region at a higher frame rate than the predetermined frame rate.

A non-transitory computer-readable recording medium recorded with an image pickup program, the image pickup program causing a computer to execute procedures of: continuously acquiring image data at a predetermined frame rate with a sensor provided on a laminated sensor and including a plurality of pixels; obtaining, in a circuit on a different layer from the sensor, a priority region including some pixels of the plurality of pixels, based on the image data; and obtaining outputs of the some pixels included in the priority region at a higher frame rate than the predetermined frame rate.

### BRIEF DESCRIPTION OF THE DRAWINGS

FIG. 1 is a block diagram illustrating a circuit configuration of an image pickup apparatus adopting a laminated image pickup device according to a first embodiment of the present invention;

FIG. 2 is a perspective view schematically illustrating an example of a configuration of the laminated image pickup device according to the first embodiment;

FIG. 3 is an explanatory diagram illustrating a process in which a priority region is judged by a region judgement portion 14;

FIG. 4 is an explanatory diagram illustrating the process in which the priority region is judged by the region judgement portion 14;

FIG. 5 is an explanatory diagram illustrating the process in which the priority region is judged by the region judgement portion 14;

FIG. 6 is a flowchart illustrating an operation of the first embodiment;

FIG. 7 is a block diagram illustrating a second embodiment of the present invention;

FIG. 8 is a perspective view schematically illustrating an example of a configuration of a laminated image pickup device in FIG. 7;

FIG. 9 is an explanatory diagram illustrating learning for generating an inference model adopted by an inference engine 72;

FIG. 10 is a flowchart illustrating a creation of training data;

FIG. 11 is a block diagram illustrating a third embodiment of the present invention;

FIG. 12 is an explanatory diagram illustrating a state of photographing by an image pickup apparatus 100; and

FIG. 13 is an explanatory diagram illustrating a photographing result.

### DETAILED DESCRIPTION OF PREFERRED EMBODIMENTS

Embodiments of the present invention will be described in detail below with reference to the drawings.

### First Embodiment

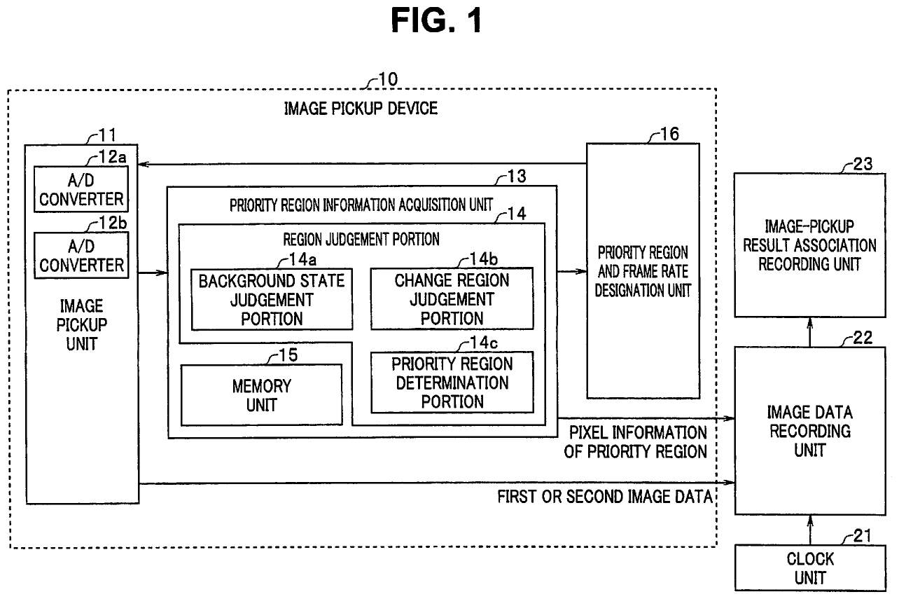

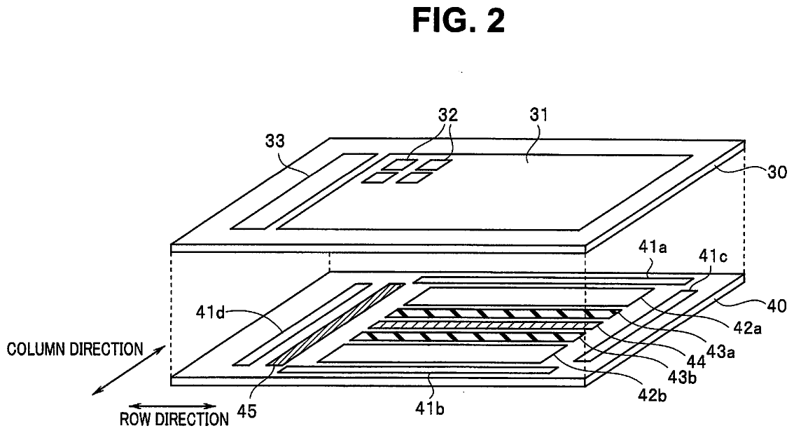

FIG. 1 is a block diagram illustrating a circuit configuration of an image pickup apparatus adopting a laminated image pickup device according to a first embodiment of the present invention. In addition, FIG. 2 is a perspective view schematically illustrating an example of a configuration of the laminated image pickup device according to the first embodiment.

In the present embodiment, only some of pixel regions (hereinafter, referred to as priority regions) in all effective pixel regions configured in a sensor unit of the image pickup device is read, and thus a high reading frame rate can be achieved. In such a case, according to the present embodiment, a priority region to be read is estimated according to a predetermined rule, for example, based on an image formed by effective pixels of all effective pixel regions. The priority region limits a read region, and may be called a limited image acquisition region.

First, a configuration of a laminated image pickup device 10 will be described with reference to FIG. 2.

The image pickup device 10 is a semiconductor device having a structure in which a sensor substrate 30 and a signal processing substrate 40 are laminated together. The sensor substrate 30 includes a sensor unit 31 in which pixels 32 for an image pickup are arranged in a two-dimensional array in a row direction and a column direction of the sensor substrate 30, each of the pixels performing photoelectric conversion. The pixel 32 photoelectrically converts incident light to generate a pixel value according to the amount of incident light. A row selection unit 33 drives each of the pixels 32 of the sensor unit 31 in units of row, reads the pixel value retained in each of the pixels 32 as a pixel signal, and outputs the pixel signal.

Vias (not illustrated) are provided in the sensor substrate 30, and vias 41a to 41d are provided at four edge parts of the signal processing substrate 40. The pixel signal outputted from the pixel 32 is supplied from the vias formed in the sensor substrate 30 to A/D converters 42a and 42b of the signal processing substrate 40 through the vias 41a to 41d formed in the signal processing substrate 40.

The signal processing substrate 40 includes the vias 41a and 41b, the A/D converters 42a and 42b, memory units 43a and 43b, and a processing circuit unit 44 that are formed from both end sides in the column direction of the signal processing substrate 40 toward a center. In other words, the memory 43a, the A/D converter 42a, and the via 41a are disposed from the processing circuit unit 44 toward the one end of the signal processing substrate 40 in the column direction, and the memory 43b, the A/D converter 42b, and the via 41b are disposed from the processing circuit unit 44 toward the other end of the signal processing substrate 40 in the column direction. The A/D converters 42a and 42b, the memory units 43a and 43b, and the processing circuit unit 44 extend in the row direction, and a read control unit 45 is disposed between end parts in the row direction of the A/D converters 42a and 42b, the memory units 43a and 43b, and the processing circuit unit 44 and the via 41d to extend in the column direction.

The pixel signal supplied from the sensor unit 31 through the vias 41a to 41d is supplied to the A/D converters 42a and 42b. The A/D converter 42a converts the inputted pixel signal into a digital signal, and then gives the digital signal to the memory unit 43a to be stored. In addition, the A/D converter 42b converts the inputted pixel signal into a digital signal, and then gives the digital signal to the memory unit 43b to be stored.

A pixel signal is given to the A/D converter 42a from the pixel in a predetermined region of the sensor unit 31, and a pixel signal is given to the A/D converter 42b from the pixel in the other predetermined region of the sensor unit 31. For example, the sensor unit 31 is divided into two regions in the row direction, a pixel signal may be given to the A/D converter 42a from the each of the pixels 32 in one region, and a pixel signal may be given to the A/D converter 42b from each of the pixels 32 in the other region. In addition, for example, the sensor unit 31 is divided into two regions in the column direction, a pixel signal may be given to the A/D converter 42a from the each of the pixels 32 in one region, and a pixel signal may be given to the A/D converter 42b from each of the pixels 32 in the other region.

Thereby, the reading from each of the pixels 32 of the sensor unit 31 can be performed at a high speed by parallel processing. Further, a switch circuit is provided so that the pixels supplying the pixel signals to the A/D converters 42a and 42b can be switched, and thus the pixel signals can be given to the A/D converters 42a and 42b from the pixels in a desired region of the sensor unit 31.

The processing circuit unit 44 is configured by a logic circuit to determine a priority region and a frame rate and to control the read control unit 45.

The read control unit 45 controls the row selection unit 33 to control the reading of the pixel signal from the sensor unit 31 and controls writing and reading of the pixel signal to and from the memory units 43a and 43b. The read control unit 45 outputs the pixel signal to the outside of the image pickup device 10.

In this way, the sensor unit 31 can be configured substantially in the entire region of the sensor substrate 30 by the laminated structure of the sensor substrate 30 and the signal processing substrate 40. Thus, it is also possible to reduce the size of the image pickup device 10 without reducing the number of pixels.

The configuration of FIG. 2 is an example. For example, the A/D converter 42a and the A/D converter 42b can also be formed on the sensor substrate 30. Further, for example, the memory units 43a and 43b can be formed on an independent substrate different from the sensor substrate 30 and the signal processing substrate 40, and the image pickup device 10 can also be configured as a semiconductor device having a three-layer structure.

In FIG. 1, the image pickup device 10 includes an image pickup unit 11, a priority region information acquisition unit 13, and a priority region and frame rate designation unit 16. The image pickup unit 11 in FIG. 1 corresponds to the sensor substrate 30 in FIG. 2, the priority region information acquisition unit 13 corresponds to the processing circuit unit 44 and the memory units 43a and 43b, and the priority region and frame rate designation unit 16 corresponds to the processing circuit unit 44 and the read control unit 45. FIG. 1 illustrates an example in which A/D converters 12a and 12b respectively corresponding to the A/D converters 42a and 42b in FIG. 2 is configured in the image pickup unit 11, but may be configured on the signal processing substrate 40 as illustrated in FIG. 2.

Each of the units in the priority region information acquisition unit 13 and the priority region and frame rate designation unit 16 may be configured by a processor using, for example, a CPU (central processing unit) or an FPGA (field programmable gate array), may be operated according to a program stored in a memory (not illustrated) to control each of the units, or may realize some or all of functions with an electronic circuit of hardware.

The image pickup unit 11 picks up an image of an object with the pixels 32, and acquires a picked-up image. The A/D converters 12a and 12b converts the image picked up by the image pickup unit 11 into a digital signal, and supplies the digital signal to the priority region information acquisition unit 13. The priority region information acquisition unit 13 includes a region judgement portion 14 and a memory unit 15. The priority region information acquisition unit 13 gives the inputted picked-up image to the memory unit 15 to be stored.

The region judgement portion 14 is configured to determine, according to a predetermined rule, some of the priority regions in all effective pixel regions configured in the sensor unit 31. For example, in the present embodiment, the region judgement portion 14 determines the region on the sensor unit 31 configured to capture a moving object included in the picked-up image obtained by the image pickup unit 11 as the priority region. The region judgement portion 14 outputs information on the priority region to the priority region and frame rate designation unit 16.

The priority region and frame rate designation unit 16 controls the image pickup unit 11 to read the picked-up image from the pixels 32 included in the priority region designated by the region judgement portion 14. In such a case, the priority region and frame rate designation unit 16 controls the frame rate according to the number of pixels 32 to be read. For example, the priority region and frame rate designation unit 16 increases the frame rate as the number of pixels to be read from the sensor unit 31 decreases. For example, when the number of pixels corresponding to 1/n (n is a natural number) of all pixels is read, the priority region and frame rate designation unit 16 can also set a frame rate that is n times as high as a normal frame rate at the time of reading all pixels (hereinafter referred to as a normal frame rate).

FIG. 1 illustrates an example in which the region judgement portion 14 is configured by a logic circuit. In other words, the region judgement portion 14 includes a background state judgement portion 14a, a change region judgement portion 14b, and a priority region determination portion 14c.

The background state judgement portion 14a judges a state of a background part of the picked-up image stored in the memory unit 15. For example, when there is no change in the image of the region (background judgement region) in the picked-up image set as the background part, the background state judgement portion 14a judges that the background judgement region is a background region.

The change region judgement portion 14b of the region judgement portion 14 judges a moving object in the picked-up image stored in the memory unit 15. For example, the change region judgement portion 14b may judge a change in the image with respect to a change judgement region that is assumed as a region in which the moving object exists, and thus may judge whether the change judgement region is a change region in which the moving object exists. In addition, the change region judgement portion 14b may judge that a small region in the change judgement region in which the moving object exists is the change region. Further, the change region judgement portion 14b may be configured to judge a motion of the moving object in the change judgement region and output a judgement result.

The priority region determination portion 14c determines the priority region based on the judgement results of the background state judgement portion 14a and the change region judgement portion 14b. For example, the priority region determination portion 14c may determine a predetermined region including the moving object as the priority region. In addition, for example, the priority region determination portion 14c may determine that the region judged as the change region by the change region judgement portion 14b is the priority region, or may determine that the region including the region judged as the change region is the priority region.

Further, the priority region determination portion 14c may be configured to receive the judgement result of the motion of the object in the change judgement region from the change region judgement portion 14b and change a position and a size of the priority region with respect to the picked-up image, based on the judgement result. Alternatively, the priority region determination portion 14c may be configured to change the position and the size of the priority region with respect to the picked-up image, based on the change in the position of the change region.

The region judgement portion 14 judges a priority region using at least two picked-up images. In addition, the region judgement portion 14 may be configured to judge the priority region at a predetermined time interval.

A high-speed image pickup of a portion having a large motion is mainly described above, but it may be considered to be an application for a high-speed image pickup of an important partial image. In such a case, the priority region may be referred to as an important region, and may be not the region having the large motion but a region for observing so as not to overlook a slight change. In addition, the priority region may be an ambush region so as not to miss a moment when an image of any object is picked up.

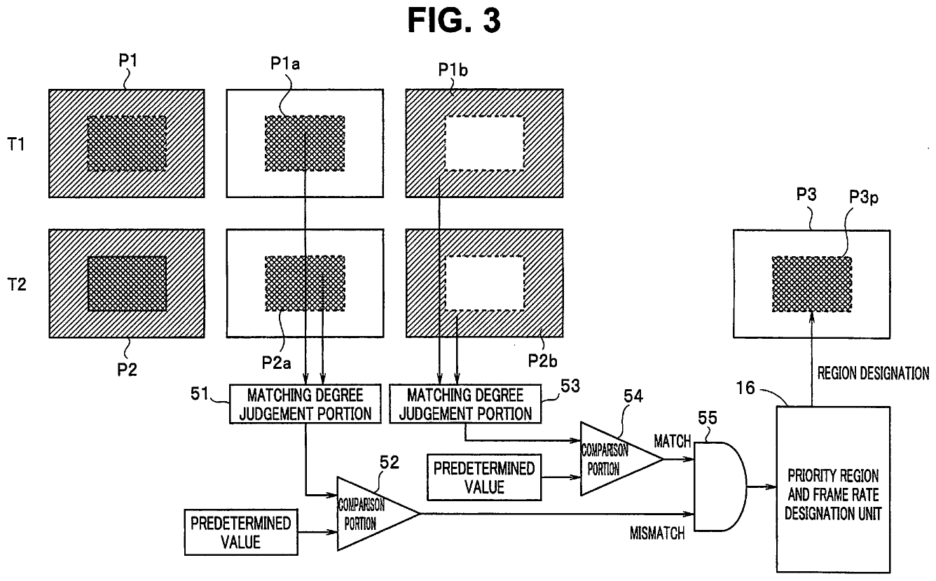

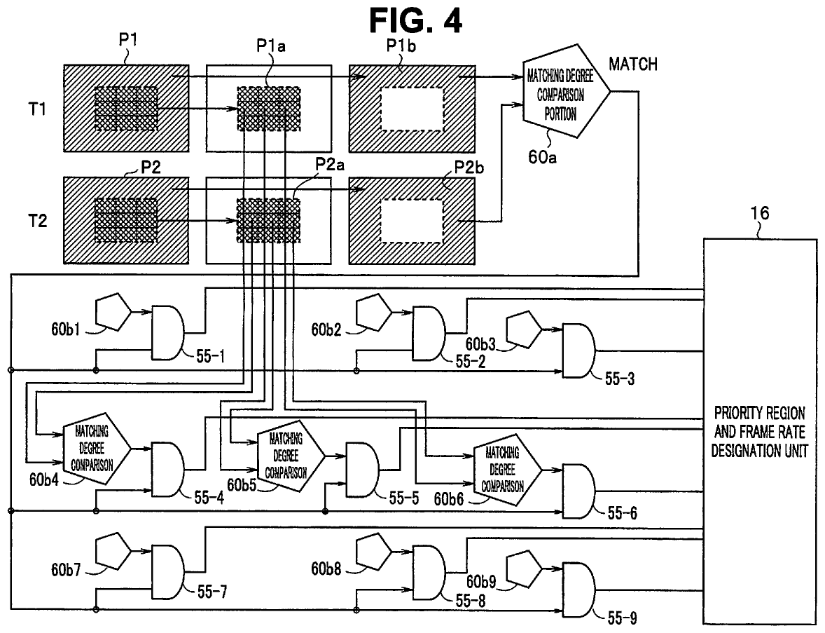

FIGS. 3 to 5 are explanatory diagrams illustrating processes in which the priority region is judged by the region judgement portion 14. FIGS. 3 and 4 illustrate an example of a specific configuration of the region judgement portion 14.

FIG. 3 illustrates an example in which a central part of the picked-up image is set as a change judgement region and surroundings of the picked-up image is set as a background judgement region in order to simplify the processing of the region judgement portion 14. FIG. 3 illustrates an example in which the priority region is determined by processing picked-up images P1 and P2 obtained by the image pickup unit 11 at two times T1 and T2, that is, at predetermined time intervals.

FIG. 3 illustrates an example in which the change region judgement portion 14b is configured by a matching degree judgement portion 51 and a comparison portion 52, the background state judgement portion 14a is configured by a matching degree judgement portion 53 and a comparison portion 54, and the priority region determination portion 14c is configured by a logic circuit 55.

The matching degree judgement portion 51 judges a matching degree between an image in a central change judgement region P1a in the picked-up image P1 acquired at time T1 and an image in a central change judgement region P2a in the picked-up image P2 acquired at time T2. For example, the matching degree judgement portion 51 may judge the matching degree by obtaining the correlation between the image in the change judgement region P1a and the image in the change judgement region P2a. The judgement result of the matching degree from the matching degree judgement portion 51 is given to the comparison portion 52. The comparison portion 52 compares the judgement result of the matching degree from the matching degree judgement portion 51 with a predetermined value to judge whether the image in the change judgement region P1a matches the image in the change judgement region P2a and to output the judgement result to the logic circuit 55.

The matching degree judgement portion 53 judges a matching degree between an image in a surrounding background judgement region P1b in the picked-up image P1 acquired at time T1 and an image in a surrounding background judgement region P2b in the picked-up image P2 acquired at time T2. For example, the matching degree judgement portion 53 may judge the matching degree by obtaining the correlation between the image in the background judgement region P1b and the image in the background judgement region P2b. The judgement result of the matching degree from the matching degree judgement portion 53 is given to the comparison portion 54. The comparison portion 54 compares the judgement result of the matching degree from the matching degree judgement portion 53 with a predetermined value to judge whether the image in the background judgement region P1b matches the image in the background judgement region P2b and to output the judgement result to the logic circuit 55.

The logic circuit 55 outputs, to the priority region and frame rate designation unit 16, information indicating that the change judgement region is a change region when the output of the comparison portion 52 indicates a mismatch and the output of the comparison portion 54 indicates a match. In such a case, the priority region and frame rate designation unit 16 sets the region of the sensor unit 31 corresponding to a central change judgement region P3p of a picked-up image P3 inputted after the next timing as a priority region (read region), and controls to output the pixel signal only from the pixel (read pixel) included in the read region. In addition, the priority region and frame rate designation unit 16 sets the frame rate according to the size of the read region (the number of read pixels). For example, when the number of read pixels is ¼ of the number of all effective pixels of the sensor unit 31, the priority region and frame rate designation unit 16 can also set a frame rate that is four times the normal frame rate at the time of reading the pixel signals of all effective pixels.

When the output of the comparison portion 54 indicates a mismatch, the logic circuit 55 judges that there is a motion in the background judgement region and outputs, to the priority region and frame rate designation unit 16, information indicating that the priority region is not set. Further, when the output of the comparison portion 52 indicates a match, the logic circuit 55 judges that there is no motion in the change judgement region and outputs, to the priority region and frame rate designation unit 16, information indicating that the priority region is not set. In such a case, the priority region and frame rate designation unit 16 controls to read the pixel signals from all effective pixels of the sensor unit 31.

FIG. 3 illustrates an example in which the background judgement region and the change judgement region are fixed and the region judgable as the change region is limited to the center of the picked-up image. However, the surroundings of the picked-up image may be desirably set as the priority region depending on the position or the state of the motion of the moving object.

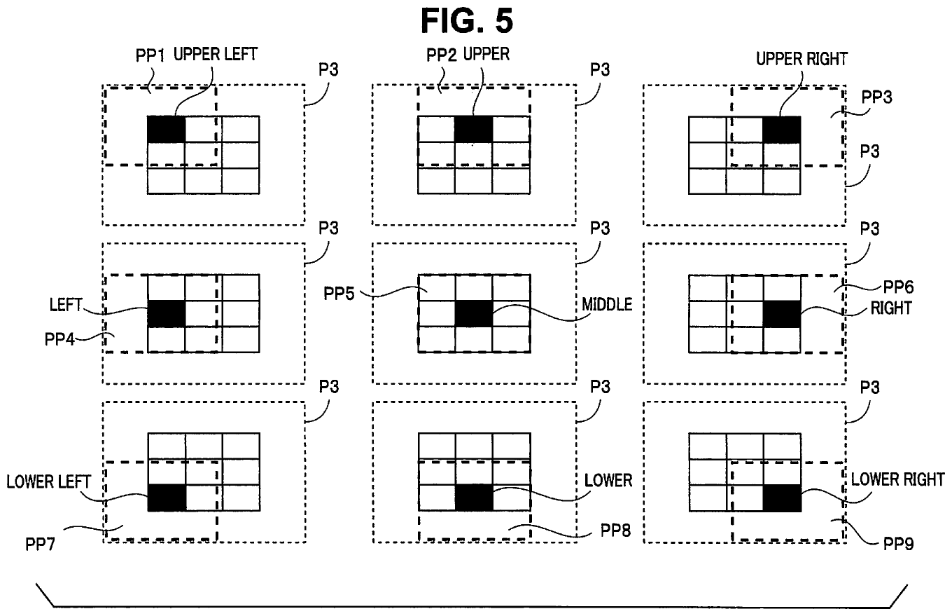

FIGS. 4 and 5 correspond to such a case, and illustrate an example in which the effective pixel region of the sensor unit 31 is divided into 25 division regions (five vertical regions×five horizontal regions) (see FIG. 5), and nine division regions (three vertical regions×three horizontal regions) can be set as priority regions. In other words, nine places in the picked-up image can be set as candidates of the priority regions, and one of nine places can be set as a priority region. FIG. 4 illustrates an example in which nine division regions (3×3) located at the center in 25 division regions are set as change judgement regions and the surrounds are set as background judgement regions. In FIG. 4, the priority region also is determined by processing the picked-up images P1 and P2 obtained by the image pickup unit 11 at two times T1 and T2, that is, at predetermined time intervals.

In FIG. 4, a matching degree comparison portion 60a is configured by the matching degree judgement portion 53 and the comparison portion 54 in FIG. 3, and matching degree comparison portions 60b1 to 60b9 are configured by the matching degree judgement portion 51 and the comparison portion 52 in FIG. 3, respectively. FIG. 4 illustrates an example in which the change region judgement portion 14b is configured by the matching degree comparison portions 60b1 to 60b9, the background state judgement portion 14a is configured by the matching degree comparison portion 60a, and the priority region determination portion 14c is configured by logic circuits 55-1 to 55-9.

The matching degree comparison portion 60a judges a matching degree between the image in the surrounding background judgement region P1b in the picked-up image P1 acquired at time T1 and the image in the surrounding background judgement region P2b in the picked-up image P2 acquired at time T2. For example, the matching degree comparison portion 60a compares the judgement result of the matching degree with a predetermined value to judge whether the image in the background judgement region P1b matches the image in the background judgement region P2b and to output the judgement result to the logic circuits 55-1 to 55-9.

The matching degree comparison portions 60b1 to 60b9 judge, for each division region, a matching degree between the image in the central change judgement region P1a in the picked-up image P1 acquired at time T1 and the image in the central change judgement region P2a in the picked-up image P2 acquired at time T2. The change judgement regions P1a and P1b are divided into nine division regions (three vertical regions×three horizontal regions) of an upper left region, an upper region, an upper right region, a left region, a middle region, a right region, a lower left region, a lower region, and a lower right region, respectively. Images of these division regions are given to the matching degree comparison portions 60b1 to 60b9, respectively, and the matching degree is judged for each division region. Note that FIG. 4 illustrates only a case where the left, middle, and right division regions are connected for the sake of simplification of the drawing.

Each of the matching degree comparison portions 60b1 to 60b9 compares the matching degree with a predetermined value to judge, for each division region, whether the image in the change judgement region P1a matches the image in the change judgement region P2a and to output the judgement result to each of the logic circuits 55-1 to 55-9.

When at least one of the outputs of the matching degree comparison portions 60b1 to 60b9 indicates a mismatch and the output of the matching degree comparison portion 60a indicates a match, each of the logic circuits 55-1 to 55-9 outputs, to the priority region and frame rate designation unit 16, information indicating that the mismatched division region in the change judgement region is a change region. When receiving the information indicating that the predetermined division region is the change region, the priority region and frame rate designation unit 16 sets, as a priority region, the region including nine division regions (three vertical regions×three horizontal regions) arranged at the center of the picked-up image P3 inputted after the next timing.

Except when at least one of the outputs of the matching degree comparison portions 60b1 to 60b9 indicates a mismatch and the output of the matching degree comparison portion 60a indicates a match, each of the logic circuits 55-1 to 55-9 outputs, to the priority region and frame rate designation unit 16, information indicating that the priority region is not set.

FIG. 5 illustrates setting of the priority region. A priority region PP1 indicates a priority region when an upper left division region of the change judgement region at the center in the picked-up image P3 is judged to be the change region. Similarly, priority regions PP2 to PP9 indicate priority regions, respectively, when an upper, an upper right, a left, a middle, a right, a lower left, a lower, or a lower right division region of the change judgement region at the center in the picked-up image P3 is judged to be the change region of the priority region at the center in the picked-up image P3 is judged to be the change region.

In the examples of FIGS. 3 to 5 described above, the change region is obtained and the priority region is judged for the two picked-up images, but the position and the size of the priority region with respect to the picked-up image may be changed based on the change of the change region in the predetermined period and the change of the motion of the object in the predetermined period. In FIGS. 4 and 5, the division region and the priority region candidate can be appropriately set and changed in size.

In the examples of FIGS. 3 to 5 described above, the change region is judged for the preset change judgement region and the priority region is set, but the priority region may be set by detection of the moving object in the entire screen. For example, a main object, a specific animal, a person, or a ball in sports is detected by image recognition, and thus a region including a plurality of pixels of the sensor unit 31 configured to capture these moving objects may be set as a priority region.

In the examples of FIGS. 4 and 5, the number of pixels included in the priority region is ¼ of the number of all effective pixels of the sensor unit 31, and the frame rate for reading from the priority region can be set to be four times as high as the normal frame rate. In addition, the priority region candidate is one region located at the center of the sensor unit 31 in the example of FIG. 3, and the priority region candidates are known nine regions of the sensor unit 31 in the examples of FIGS. 4 and 5. Accordingly, a switch circuit is configured such that the pixel signals of the pixels included in these priority region candidates are distributed and supplied to the A/D converters 42a and 42b in FIG. 2, and thus the reading from the priority region can also be performed at a high speed by parallel processing.

In FIG. 1, after determining the priority region, the priority region information acquisition unit 13 reads only the pixel signal of the pixel in the priority region from the image pickup unit 11 and causes the memory unit 15 to store the pixel signal. The memory unit 15 outputs information (pixel information) on the pixel signal of the priority region to an image data recording unit 22.

The image data recording unit 22 is configured by a predetermined recording medium, and records the inputted pixel information of the priority region. A clock unit 21 outputs time information to the image data recording unit 22, and the image data recording unit 22 adds the time information to the pixel information of the priority region and records the resultant information. In addition, the image data recording unit 22 acquires image data (first or second image data) of the two picked-up images (picked-up images P1 and P2 in FIGS. 3 and 4) used for determining the priority region from the image pickup unit 11 and records the acquired data.

An image-pickup result association recording unit 23 is configured by a predetermined recording medium, and records first or second image pickup data based on all effective pixels of the sensor unit 31 and the image information and the time information of the priority region in association with each other.

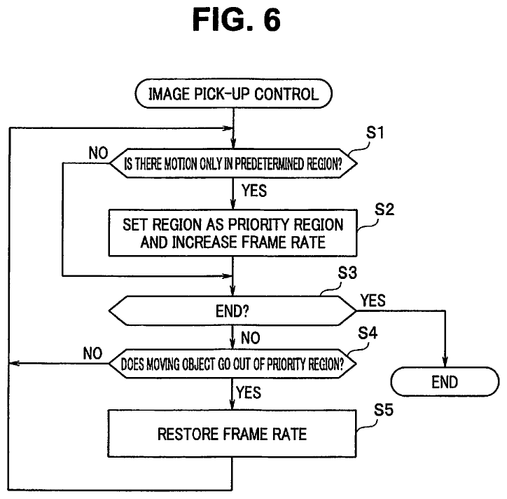

An operation of the embodiment configured as described above will be described below with reference to FIG. 6. FIG. 6 is a flowchart illustrating the operation of the embodiment.

The image pickup unit 11 of the image pickup device 10 picks up an image of a predetermined object. The image picked up by the image pickup unit 11 is converted into a digital signal by the A/D converters 12a and 12b, and then is given to the memory unit 15 of the priority region information acquisition unit 13 to be stored. The priority region information acquisition unit 13 causes the memory unit 15 to store two picked-up image. The region judgement portion 14 judges, in step S1 of FIG. 6, whether there is a motion in the image for a predetermined region in the picked-up image.

In other words, the background state judgement portion 14a and the change region judgement portion 14b judge a change state of the image in the background judgement region or the change judgement region for each of the two picked-up images based on the matching degree, and obtain the judgement result of a match or a mismatch. The priority region determination portion 14c sets all or a part of the change judgement regions as the change region and determines the priority region including the change region only when the background judgement regions match and all or a part of the change judgement regions does not match.

The region judgement portion 14 outputs information on the priority region to the priority region and frame rate designation unit 16. In step S2, the priority region and frame rate designation unit 16 sets the region designated by the region judgement portion 14 as the priority region, sets the frame rate at the time of reading the priority region to a high speed, and designates the priority region and the frame rate to the image pickup unit 11.

Thus, the image pickup unit 11 outputs the pixel signal from the priority region at a high-speed frame rate. For example, when the number of pixels in the priority region is ¼ of the number of all effective pixels, the reading can be performed at the frame rate four times as high as the normal frame rate at which all pixels are read. The pixel signal of the priority region is given to the memory unit 15 to be stored.

The pixel information on the pixel signal of the priority region stored in the memory unit 15 is supplied to the image data recording unit 22, and is stored together with the time information outputted from the clock unit 21. In addition, the picked-up image used for judging the priority region is also supplied to the image data recording unit 22 to be stored. The image-pickup result association recording unit 23 records the picked-up image and the pixel information and the time information of the priority region, which are stored in the image data recording unit 22, in association with each other.

The region judgement portion 14 judges whether the end of the image pickup is instructed (step S3). When the end of the image pickup is instructed, the image pickup control is ended.

For example, it is assumed that an image of a soccer game is picked up in a normal photographing mode in which all pixels of the sensor unit 31 are read. When the image pickup control of FIG. 6 is executed in a state where a soccer ball is captured in the approximate center of the image pickup range, the pixels in the predetermined priority region capturing the soccer ball can be read at a frame rate higher than the normal frame rate. For example, the priority region is ¼ of the all effective pixel regions and the normal frame rate is 30 fps, high-speed photographing can be performed at 120 fps. Thereby, it is possible to improve the image quality of the range including the soccer ball, and is also possible to confirm the motion such as a rotation of the soccer ball in more detail by slow-playing the recorded image.

The region judgement portion 14 can move the priority region and can also continue to pick up an image of the priority region including the moving object by predicting the motion of the moving object, for example. In addition, the change region is detected at every predetermined time using the method in FIGS. 4 and 5, and thus it is also possible to continue to pick up an image of the priority region including the moving object.

However, when the moving object is faster than the motion of the image pickup device 10 (motion in a visual field range of the image pickup unit 11), or when moving faster than the motion predicted by the region judgement portion 14, the moving object may be located out of the priority region. Therefore, when judging in step S3 that the end of the image pickup is not instructed, the region judgement portion 14 judges in subsequent step S4 whether the moving object captured by the pixel in the priority region goes out of the priority region (being no longer captured by the pixel in the priority region). When the moving object goes out of the priority region, the region judgement portion 14 gives, to the priority region and frame rate designation unit 16, information that the priority region does not exist.

Thus, the priority region and frame rate designation unit 16 returns the frame rate to the normal frame rate in step S5, and instructs the image pickup unit 11 not to set the priority region. Thus, in such a case, the image pickup unit 11 outputs the pixel signals of all effective pixels at the normal frame rate.

As described above, according to the present embodiment, a part of all effective pixel regions in which the moving image is captured is estimated as the priority region to be read, and the pixel signal is read only for the pixel in such a priority region. Thereby, the reading can be performed at the frame rate higher than the normal frame rate. The setting of the priority region is performed by the processing circuit unit mounted on the signal processing substrate laminated on the sensor substrate in which the pixels are formed. With the laminated structure, the size of the sensor substrate can be made smaller compared with the size of the sensor substrate with the same number of pixels without the laminated structure, and the image of the priority region can be outputted at a high-speed frame rate due to the small image pickup device.

### Second Embodiment

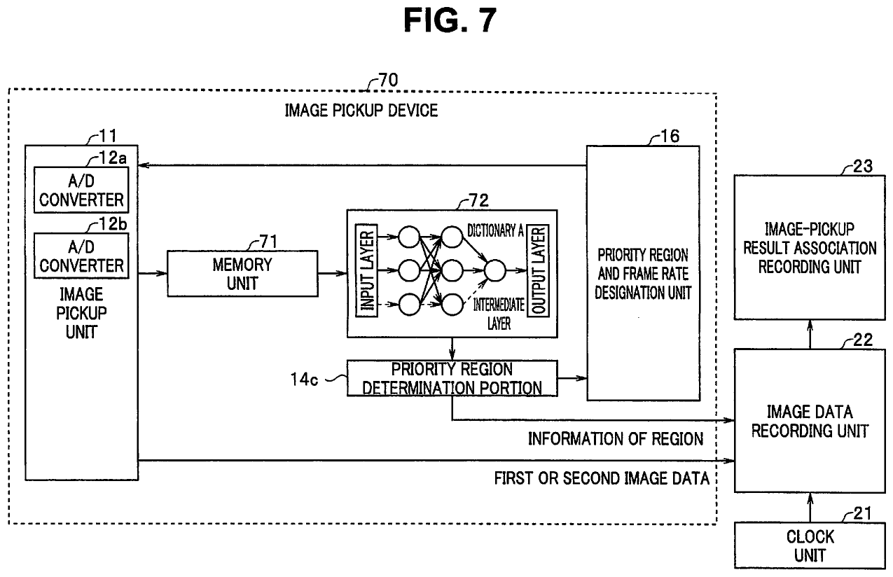

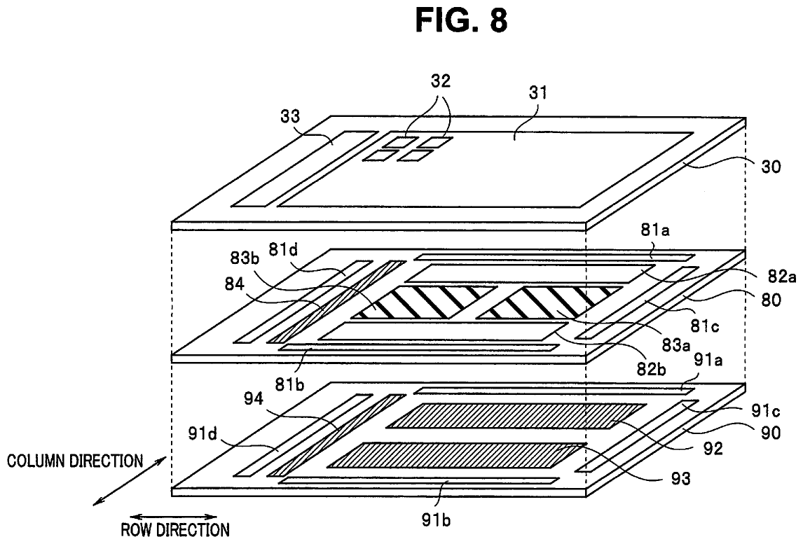

FIG. 7 is a block diagram illustrating a circuit configuration of an image pickup apparatus according to a second embodiment of the present invention. Further, FIG. 8 is a perspective view schematically illustrating an example of a configuration of a laminated image pickup device in FIG. 7. In FIGS. 7 and 8, the same components as the components in FIGS. 1 and 2 are denoted by the same reference numerals and will not be presented.

The priority region is determined by the processing circuit unit 44 configured by the logic circuits in the first embodiment. On the other hand, the priority region is determined by an inference device in the present embodiment.

In the present embodiment, an example will be described in which a laminated image pickup device 70 having a three-layer structure is adopted. An image pickup device 70 may be configured to have a two-layer structure.

First, a configuration of an image pickup device 70 will be described with reference to FIG. 8.

The image pickup device 70 is a semiconductor device having a structure in which a sensor substrate 30, a memory substrate 80 and a signal processing substrate 90 are laminated together. Vias 81a to 81d are provided at four edge parts of the memory substrate 80, and vias 91a to 91d are provided at four edge parts of the signal processing substrate 90. Each of the vias 81a to 81d and each of the vias 91a to 91d can be electrically connected to each other.

The pixel signal outputted from the pixel 32 is supplied from the vias formed in the sensor substrate 30 to A/D converters 82a and 82b of the memory substrate 80 through the vias 81a to 81d formed in the memory substrate 80.

The memory substrate 80 includes memory units 83a and 83b that are formed at the center of the memory substrate 80 in the column direction. The A/D converter 82a and the via 81a are disposed from the memory units 83a and 83b toward the one end of the memory substrate 80 in the column direction, and the A/D converter 82b, and the via 81b are disposed from the memory units 83a, 83b toward the other end of the memory substrate 80 in the column direction. Each of the A/D converters 82a and 82b extend in the row direction, and the memory units 83a and 83b are arranged side by side in the row direction. A read control unit 84 is disposed between end parts in the row direction of the A/D converters 82a and 82b and the memory units 83a and 83b, and the via 81d to extend in the column direction.

The pixel signal supplied from the sensor unit 31 through the vias 81a to 81d is supplied to the A/D converters 82a and 82b. The A/D converter 82a converts the inputted pixel signal into a digital signal, and then gives the digital signal to the memory unit 83a to be stored. In addition, the A/D converter 82b converts the inputted pixel signal into a digital signal, and then gives the digital signal to the memory unit 83b to be stored.

A pixel signal is given to the A/D converter 82a from the pixel in a predetermined region of the sensor unit 31, and a pixel signal is given to the A/D converter 82b from the pixel in the other predetermined region of the sensor unit 31. For example, the sensor unit 31 is divided into two regions in the row direction, a pixel signal may be given to the A/D converter 82a from the each of the pixels 32 in one region, and a pixel signal may be given to the A/D converter 82b from each of the pixels 32 in the other region. In addition, for example, the sensor unit 31 is divided into two regions in the column direction, a pixel signal may be given to the A/D converter 82a from the each of the pixels 32 in one region, and a pixel signal may be given to the A/D converter 82b from each of the pixels 32 in the other region.

Thereby, the reading from each of the pixels 32 of the sensor unit 31 can be performed at a high speed by parallel processing. Further, a switch circuit is provided so that the pixels supplying the pixel signals to the A/D converters 82a and 82b can be switched, and thus the pixel signals can be given to the A/D converters 82a and 82b from the pixels in a desired region of the sensor unit 31.

The read control unit 84 controls the row selection unit 33 to control the reading of the pixel signal from the sensor unit 31 and controls writing and reading of the pixel signal to and from the memory units 83a and 83b. The read control unit 84 outputs the pixel signal to the signal processing substrate 90 and also outputs the pixel signal to the outside of the image pickup device 70.

The signal processing substrate 90 includes the via 91a and the inference engine 92 that are disposed from the one end of the signal processing substrate 90 in the column direction toward the center to extend in the column direction and includes the via 91b and the processing circuit unit 93 that are disposed from the other end of the signal processing substrate 90 toward the center to extend in the column direction.

The pixel signal supplied from the memory substrate 80 through the vias 91a to 91d is supplied to the inference engine 92. The inference engine 92 infers a priority region in the image based on the inputted pixel signal, and outputs the inference result to the processing circuit unit 93.

The processing circuit unit 93 determines a frame rate, and outputs information on the priority region and the frame rate to the read control setting unit 94. The read control setting unit 94 transfers the information on the priority region and the frame rate to the read control unit 84.

In this way, the sensor unit 31 can be configured substantially in the entire region of the sensor substrate 30 by the laminated structure of the sensor substrate 30, the memory substrate 80 and the signal processing substrate 90. Thus, it is also possible to reduce the size of the image pickup device 70 without reducing the number of pixels.

The configuration of FIG. 8 is an example, and a laminated image pickup device 70 may be configured by a two-layer structure as in FIG. 2.

In FIG. 7, the image pickup device 70 includes an image pickup unit 11, a memory unit 71, an inference engine 72, a priority region determination portion 14c, and a priority region and frame rate designation unit 16. In FIG. 7, the image pickup unit 11 corresponds to a sensor substrate 30 in FIG. 8, the memory unit 71 corresponds to memory units 83a and 83b, the priority region determination portion 14c and the priority region and frame rate designation unit 16 correspond to a processing circuit unit 93, the read control unit 84, and a read control setting unit 94, respectively. FIG. 7 illustrates an example in which A/D converters 12a and 12b corresponding to the A/D converters 82a and 82b in FIG. 8, respectively, is configured in the image pickup unit 11, but may be configured on the memory substrate 80 as illustrated in FIG. 8.

The image pickup unit 11 picks up an image of an object with the pixels 32, and acquires a picked-up image. The A/D converters 82a and 82b converts the image picked up by the image pickup unit 11 into a digital signal, and supplies the digital signal to the memory unit 71 to be stored.

The inference engine 72 functions as a region judgement portion, and estimates a part of priority regions in all effective pixel regions configured in the sensor unit 31, similarly to the region judgement portion 14 in FIG. 1. For example, in the present embodiment, the inference engine 72 is configured to estimate, as a priority region, a region on the sensor unit 31 capturing a moving object included in the picked-up image obtained by the image pickup unit 11. The inference result of the inference engine 72 is given to the priority region determination portion 14c.

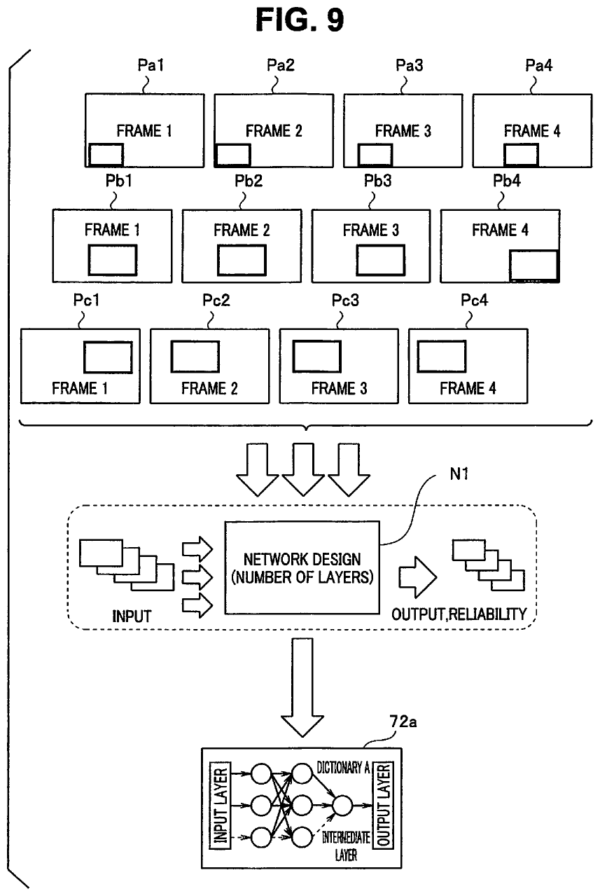

FIG. 9 is an explanatory diagram illustrating learning for generating an inference model adopted by the inference engine 72.

FIG. 9 illustrates an example in which frame images Pa1˜, Pb1˜, and Pc1˜ serving as training data shown in an upper part are given to a predetermined network N1 shown in an intermediate part to be learned and thus an inference model 72a shown in a lower part is acquired.

The frame images Pa1˜, Pb1˜, and Pc1˜ are acquired and generated from, for example, a movie site or a still image site on the predetermined network. An annotation specifying a region to be a priority region is set in each of the frame images of the acquired movie or still image, and the frame images Pa1˜, Pb1˜, and Pc1˜ to be the training data are generated.

The generation of such training data can also be automated. For example, a moving body may be detected from each of the frame images, and a region including the moving body may be set as a priority region. For example, with the circuit configuration similar to the circuit configuration of the region judgement portion 14 in FIG. 1, an annotation specifying the region based on the position and the size information of the moving body in the next frame image may be set on the previous frame image among the plurality of frame images in which the background does not change and the position of the moving body changes.

Frames in the frame images Pa1˜, Pb1˜, and Pc1˜ in FIG. 9 indicate priority regions including the position of the moving body in the next frame image out of these frame images. Positions and sizes of the frames indicating the priority region in the frame images Pa1˜, Pb1˜, and Pc1˜ are provided in consideration of the frame rate. For example, a motion amount is assumed to be ¼ and the priority region corresponding to the motion amount is set when the frame rate of the movie serving as a source of training data is 30 fps and the frame rate at the time of reading the pixel in the priority region is 120 fps.

When learning is performed with a large amount of training data, a network design of the network N1 is determined so as to obtain an output corresponding to the input. In other words, when an image is inputted by giving the training data caused by these frame images Pa1˜, Pb1˜, and Pc1˜ to the network N1 to be learned, it is possible to generate the inference model 72a that outputs information on the priority region including the position of the moving body in the next frame image and information on reliability.

Deep learning is referred to as a multi-layered architecture of a “machine learning” process using a neural network. A “feedforward neural network” is typical which sends information from the front to the back to make a judgement. In the simplest form, the feedforward neural network may be sufficient to include three layers of an input layer with N1 neurons, an intermediate layer with N2 neurons given by parameters, and an output layer with N3 neurons corresponding to the number of classes to be discriminated. Then, neurons between the input layer and the intermediate and neurons between the intermediate layer and the output layer are combined by connection weights, and a bias value is applied to the intermediate layer and the output layer, so that a logic gate is easily formed. For simple discrimination, three layers may be used, but when the number of intermediate layers is increased, a combination method of a plurality of feature values can also be learned in the machine learning. In recent years, an architecture of nine to 152 layers has become practical in view of the time required for learning, judgement accuracy, and energy consumption.

As the network N1 used for the machine learning, various known networks may be adopted. For example, R-CNN (regions with CNN features) or FCN (fully convolutional networks) using CNN (convolution neural network) may be used. This involves a process called “convolution” that compresses the feature value of the image, works with a minimum amount of processing, and is strong in pattern recognition. In addition, a “recurrent neural network” (fully connected recurrent neural network) may be used in which information flows bidirectionally to handle complicated information and cope with information analysis in which meanings change depending on the order or the sequence.

In order to realize such a technology, existing general-purpose arithmetic processing circuits such as CPUs and FPGAs may be used, but since most neural network processing is matrix multiplication, a GPU specialized for matrix calculation or a so-called Tensor Processing Unit (TPU) may be used. In recent years, a “neural network processing unit (NPU)”, which is artificial intelligence (AI) dedicated hardware, is designed to be integrated and combined with other circuits such as a CPU, and may be used as a part of a processing circuit.

Further, the inference model may be acquired using various known machine learning methods regardless of deep learning. For example, there are methods such as a support vector machine and a support vector regression. The learning herein is to calculate weight, filter coefficient, and offset of a discriminator and to use another logistic regression processing. In order to make a machine judge something, it is necessary for a human to teach the machine how to make a judgement. In the example, a method of judging an image that is derived by machine learning is used, but a rule-based method may be used in which human's empirical rules and rules acquired by a heuristic technique are applied to a specific judgement.

For example, when the inference model 72a in FIG. 9 is set in the inference engine 72 and the frame image Pa1 illustrated in FIG. 9 is picked up by the image pickup unit 11, the inference engine 72 infers the frame part in the image Pa1 and outputs, as an inference result, information on a position and a size of the frame part to the priority region determination portion 14c together with information on reliability.

The priority region determination portion 14c determines, based on the inference result of the inference engine 72, the priority region. Further, the priority region determination portion 14c may judge the motion of the object based on the inference result of the inference engine 72, and may change the position and the size of the priority region with respect to the picked-up image based on the motion judgement result. The priority region determination portion 14c outputs information on the priority region to the priority region and frame rate designation unit 16.

The inference may be performed by the inference engine 72 at predetermined time intervals.

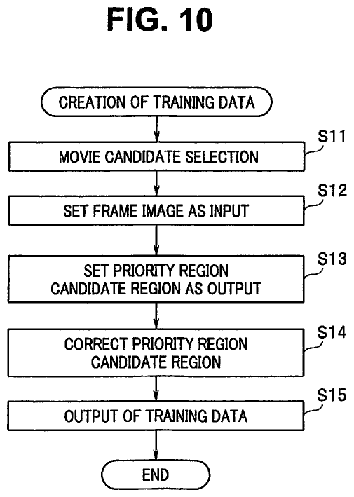

An operation of the embodiment configured as described above will be described below with reference to FIG. 10. FIG. 10 is a flowchart illustrating a creation of the training data.

The present embodiment is different from the first embodiment only in that the priority region is obtained by the inference engine 72 instead of the logic circuit. In other words, the determination of the priority region in steps S1 and S2 of the flowchart illustrated in FIG. 6 is performed by the inference engine 72 and the priority region determination portion 14c. The training data used for constructing the inference model is acquired from, for example, a movie site.

In step S11 of FIG. 10, a movie candidate is selected for setting the training data. Each of frame images of the selected movie candidate is set as an input (step S12), and a region based on the position and the size of the moving body in the frame image at the next timing out of the inputted frame images (hereinafter, referred to as a priority region candidate region) is set as an annotation. As an output, the priority region candidate region is set (step S13).

Next, the position of the priority region candidate region is corrected by assuming the frame rate at the time of reading the pixel in the priority region (step S14). For example, the frame rate at the time of reading the pixel in the priority region may be set to be higher as a ratio of the size of original image and the size of the priority region candidate region is larger. A large number of frame images with annotations set are outputted as training data (step S15).

Such training data is given to the network N1 to be learned, and thus the inference model 72a is constructed. Based on the information of the inference model 72a, the inference engine 72 is configured to implement the inference model 72a.

In the present embodiment, only one picked-up image read from the image pickup unit 11 is given to the memory unit 71 to be stored, so that the priority region is determined. The inference engine 72 infers the priority region from the one picked-up image. The inference engine 72 outputs the inference result of the priority region to the priority region determination portion 14c.

The inference engine 72 outputs the inference result of the priority region together with the information on reliability only for the picked-up image to be estimated that the background does not change and only the moving body changes

The priority region determination portion 14c determines the priority region based on the inference result of the inference engine 72, and gives the priority region to the priority region and frame rate designation unit 16. Thus, the priority region and frame rate designation unit 16 instructs the image pickup unit 11 to read only the pixel signal from the pixel included in the priority region at the frame rate higher than the normal frame rate.

The priority region determination portion 14c may change the position and the size of the priority region with respect to the picked-up image depending on the estimation result of the motion of the moving body. In addition, the inference may be performed by the inference engine 72 at predetermined time intervals. As illustrated in FIG. 6, when the moving body goes out of the priority region, the frame rate may be returned to the normal frame rate.

As described above, according to the present embodiment, the same effect as the effect in the first embodiment can be obtained, and the priority region is determined with the inference using the inference model, so that the priority region can be determined more effectively.

### Third Embodiment

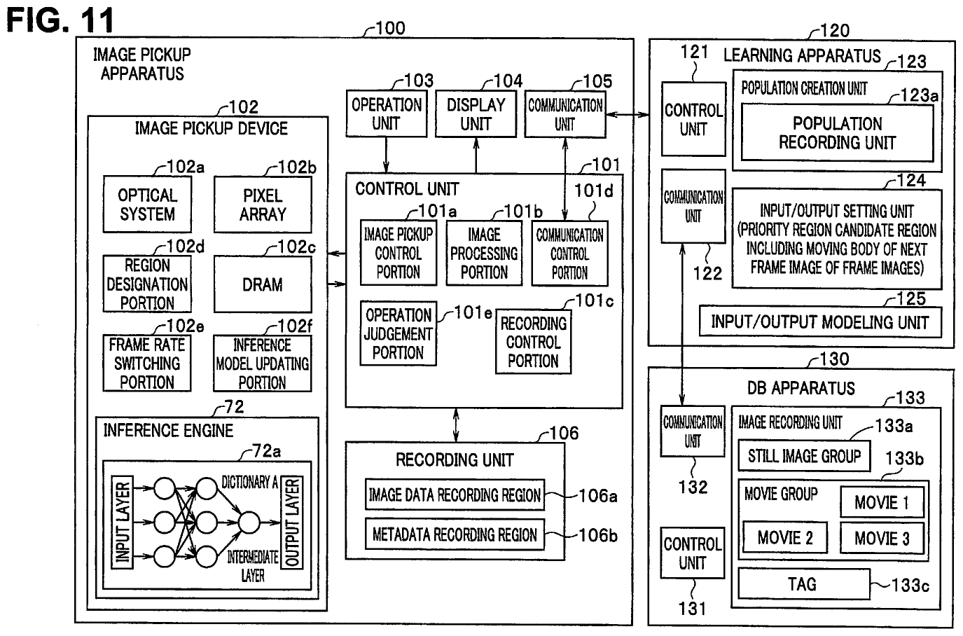

FIG. 11 is a block diagram illustrating a circuit configuration of an image pickup apparatus according to a third embodiment of the present invention. In FIG. 11, the same components as the components in FIG. 7 are denoted by the same reference numerals and will not be presented. In the present embodiment, an example is represented in which an image pickup device 102 including the inference engine 72 illustrated in FIG. 7 is applied to an image pickup apparatus 100. In the present embodiment, an inference model 72a of the image pickup device 102 can be rewritten.

As the image pickup apparatus 100 in FIG. 11, not only a digital camera or a video camera, but also a camera built in a smartphone or a tablet terminal may be adopted. Naturally, the image pickup apparatus 100 can also be applied to a camera unit of various image inspection apparatuses used in in-vehicle or process inspection, constructions, industrial fields such as security-related, or medical fields. This is because the image pickup device is downsized and the space merit can be utilized in various fields.

The image pickup apparatus 100 includes a control unit 101 configured to control each component of the image pickup apparatus 100. The control unit 101 may be configured by a processor using a CPU or an FPGA, may be operated according to a program stored in a memory (not illustrated) to control each of the components, or may realize some or all of functions with an electronic circuit of hardware.

The image pickup device 102 of the image pickup apparatus 100 may have a laminated structure in which a sensor unit, a memory unit, and a processing circuit unit are formed by separate substrates and are laminated together. The image pickup device 102 includes an optical system 102a and a pixel array 102b. The optical system 102a includes a lens for zooming and focusing and an aperture (not illustrated). The optical system 102a includes a zoom (variable magnification) mechanism (not illustrated) that drives such a lens, a focus mechanism, and an aperture mechanism.

The pixel array 102b has a configuration similar to the sensor unit 31 in FIG. 8, and is configured in which photoelectric conversion pixels of a CMOS sensor are disposed in a vertical and horizontal matrix. In the pixel array 102b, an optical image of an object is guided to each pixel of the pixel array 102b by the optical system 102a. Each pixel of the pixel array 102b photoelectrically converts the optical image of the object to acquire a picked-up image (image data) of the object.

An image pickup control portion 101a of the control unit 101 can drive and control the zoom mechanism, the focus mechanism, and the aperture mechanism of the optical system 102a to adjust the zoom, the aperture, and the focus. The image pickup device 102 picks up an image under control of the image pickup control portion 101a.

At this time, a reading cycle (frame rate) of image data from the image pickup device 102 may be changed, the control unit 101 receives and judges information on the frame rate switched by a frame rate switching portion 102e, and changes the data reading cycle. In other words, the image pickup apparatus 100 includes the image reading circuit (control unit 101) configured to switch reading control of the image data from the laminated image pickup device, based on the inference result of the inference unit (inference model 72a) provided in the laminated image pickup device to infer using an inference model (not necessarily inference, but may be logic-based judgement and switching) in which inference is performed using the image obtained by the sensor unit (pixel array 102b) of the laminated image pickup device as an input and generating information on the image of a limited image acquisition region (priority region) in all effective pixel regions of the sensor unit as an output, and thus capable of acquiring an image by fully utilizing high-speed image pickup capability of the laminated image pickup device.

For such control, the picked-up image (movie and still image) is converted into a digital signal, and then is given to a DRAM (dynamic RAM) 102c that configures the memory unit. The DRAM 102c has a configuration similar to the configuration of the memory unit 71, and stores the picked-up image. The DRAM 102c gives the stored picked-up image to the inference engine 72 for judgement of the priority region.

The inference engine 72 infers the priority region, and gives the inference result to a region designation portion 102d. The region designation portion 102d determines the priority region based on the inference result, and the frame rate switching portion 102e sets a frame rate at the time of reading the pixel in the priority region.

The pixel array 102b outputs a pixel signal in the designated priority region at the designated frame rate. The pixel signal is supplied to the DRAM 102c to be stored.

An operation unit 103 is provided in the image pickup apparatus 100. The operation unit 103 includes a release button, a function button, various switches for photographing mode settings and a parameter operation, a dial, and a ring member which are not illustrated in the drawing, and outputs an operation signal based on a user's operation to the control unit 101. An operation judgement portion 101e of the control unit 101 is configured to judge the user's operation based on the operation signal outputted from the operation unit 103, and the control unit 101 is configured to control each of the components based on the judgement result of the operation judgement portion 101e.

The image pickup control portion 101a of the control unit 101 captures the picked-up image and the image of the priority region stored in the DRAM 102c. An image processing portion 101b performs predetermined signal processing, for example, color adjustment processing, matrix conversion processing, noise removal processing, and other various kinds of signal processing on the captured picked-up image.

A display unit 104 is provided in the image pickup apparatus 100. The display unit 104 is, for example, a display device including a display screen such as an LCD (liquid crystal device), and the display screen is provided, for example, on the back surface of a housing of the image pickup apparatus 100. The control unit 101 causes the display unit 104 to display the picked-up image subjected to signal processing by the image processing portion 101b. In addition, the control unit 101 can also cause the display unit 104 to display various menu displays and warning displays of the image pickup apparatus 100.

A touch panel (not illustrated) may be provided on the display screen of the display unit 104. The touch panel, which is an example of the operation unit 103, can generate an operation signal according to a position on the display screen pointed by a user's finger. The operation signal is supplied to the control unit 101. Accordingly, the control unit 101 can detect the position touched by the user on the display screen and a slide operation in which the user slides the display screen with a finger, and can execute a process corresponding to the user's operation.

A communication unit 105 is provided in the image pickup apparatus 100, and a communication control portion 101d is provided in the control unit 101. The communication unit 105 is configured to transmit and receive information between a learning apparatus 120 and a database (DB) apparatus 130 under control of the communication control portion 101d. The communication unit 105 can make, for example, short-range wireless communication such as Bluetooth (registered trademark) and wireless LAN communication such as Wi-Fi (registered trademark). The communication unit 105 can adopt communication in various communication manners regardless of Bluetooth or Wi-Fi. The communication control portion 101d can receive inference model information (AI information) through the communication unit 105 from the learning apparatus 120. The inference model information is used to update the inference model 72a of the inference engine 72 to a model in which desired inference is performed.

A recording control portion 101c is provided in the control unit 101. The recording control portion 101c can compress the picked-up image subjected to signal processing and can give the compressed image to a recording unit 106 to be recorded. The recording unit 106 is configured by a predetermined recording medium, and can record the information given from the control unit 101 and output the recorded information to the control unit 101. In addition, as the recording unit 106, for example, a card interface may be adopted, and in this case, the recording unit 106 can record image data on the recording medium such as a memory card.

The recording unit 106 includes an image data recording region 106a, and the recording control portion 101c is configured to record the image data in the image data recording region 106a. In addition, the recording control portion 101c can also read and reproduce the information recorded in the recording unit 106.

In addition, the recording unit 106 includes a metadata recording region 106b, and the recording control portion 101c records information indicating a relation among the picked-up image recorded in the image data recording region 106a, the priority region, and the recording time in the metadata recording region 106b. History information is recorded in the metadata recording region 106b as metadata, the history information indicating that the recording is performed through certain image processing from the image outputted from the image pickup device 102 or the image data outputted from the pixel array 102b. Photographing parameter information, photographing object information, and photographing environment information are recorded as the metadata, and information with attention to image history, searchability, and evidence can be recorded in association with the image. The information may be recorded as a file similar to the image. Image correction can be performed at the time of machine learning using such information, and information about what inference model is used to pick up an image may be recorded. When the image acquired by the image pickup apparatus 100 is transferred to an external database to be recorded, a database in which the image should be recorded may be designated according to the data recorded as the metadata. It is also possible for the communication control portion 101d to judge such a content to immediately transmit the image pickup result as a candidate for training data, or select a database suitable for someone to view to transmit it to the outside. Since the result of inference for judging privacy or copyright may be reflected to improve the security at the time of recording, information on the inference result may be converted into metadata. In addition to the conversion into the training data, when an inference is performed to designate the type of the training data or the learning apparatus 120, the inference result may be recorded as metadata in the metadata recording region 106b. The inference result may be metadata used for designating the learning apparatus 120 in which learning is performed.

The image pickup device 102 includes an inference model updating portion 102f The inference model updating portion 102f can receive the inference model information received by the control unit 101 and reconstruct the inference model 72a.

In the present embodiment, the inference model information used to construct the inference model 72a is generated by the learning apparatus 120. The image pickup apparatus 100 can also supply a large number of images that are a source of the training data used for learning of the learning apparatus 120 to the learning apparatus 120. The learning apparatus 120 can also construct the inference model using only the image supplied from the image pickup apparatus 100, as training data. Further, the learning apparatus 120 can also acquire an image serving as training data from the DB apparatus 130.

In other words, an advantage of the present embodiment is to select (or to process) optimum training data from plentiful images other than obtained by the image pickup apparatus 100 and to use the data for machine learning, deep learning, and reinforcement learning. On the other hand, since the image obtained by the image pickup device 102 is inputted at the time of inference as a premise, it is also necessary to perform optimization so that the inference can be made by utilizing the characteristics of such a device. In order to effectively utilize the system of the present embodiment, a study for such optimization may be made.

The DB apparatus 130 includes a communication unit 132, and the learning apparatus 120 includes a communication unit 122. The communication units 122 and 132 have a configuration similar to the configuration of the communication unit 105, and communication can be performed between the communication units 105 and 122, between the communication units 105 and 132, and between the communication units 122 and 132.

The DB apparatus 130 includes a control unit 131 configured to control each component of the DB apparatus 130, and the learning apparatus 120 includes a control unit 121 configured to control each component of the learning apparatus 120. The control units 121 and 131 may be configured by a processor using a CPU or an FPGA, may be operated according to a program stored in a memory (not illustrated) to control each of the components, or may realize some or all of functions with an electronic circuit of hardware.

Note that the entire learning apparatus 120 may be configured by a processor using a CPU, a GPU, or an FPGA, may be operated according to a program stored in a memory (not illustrated) to control each of the components, or may realize some or all of functions with an electronic circuit of hardware.

The DB apparatus 130 includes an image recording unit 133 configured to record a large amount of learning data. In the image recording unit 133, images photographed by various image pickup apparatuses may be collected as works or evidence that have been subjected to various types of processing, and the image data obtained by the pixel array 102b of the image pickup device 102 is different in arrangement of the image data, bit width, size, noise, color tone, and exposure amount. In other words, since the image processing portion 101b of the control unit 101 performs demosaicking processing for converting the Bayer array into color RGB, sensitivity adjustment (gain adjustment), gradation correction, resolution correction, contrast, contour correction, color adjustment such as white balance, correction of aberrations and shading of the image pickup lens (optical system 102a), special effect processing and trimming, and image compression, strictly speaking, most of the images recorded in the DB apparatus 130 are results of many processes from the image data coming out from the pixel array, but cannot simply be compared on the same scale and cannot be inferred with accuracy. Since some of the image data has not been subjected to such processing at all or is image data in the middle of processing, such image data may be prioritized as training data. The processed image is made as close as possible to the data before being subjected to image processing (may be restored with gain information in a case of exposure, and may be corrected to the data before taking the white balance in a case of color adjustment) to be training data, and a balance at the time of learning is achieved by weight adjustment. Image processing information such as gain information and white balance information may be recorded in association with an image as metadata, for example. The image data processed by the image processing information recorded as metadata may be used as the training data. The image processing information also includes optical characteristic information such as aberration and shading of the optical system. In addition, the DB apparatus 130 also has an image recorded in the form of luminance data called RAW data for each color. Since being close to the data in which the image processing of image compression is not performed, such an image is information closer to the output of the pixel array 102b. Therefore, such an image may be preferentially processed (not processed) to be training data. Before the image retrieved from the database is recorded in the image processing portion 101b of the image pickup apparatus 100 or the database, a photographer performs processing (second image processing) of restoring the image to the data subjected not to image processing with a personal computer to make it training data.

In other words, since the inference unit (inference engine 72) provided in the laminated image pickup device (image pickup device 102) is optimized to perform inference using the image data obtained by the sensor unit (pixel array 102b) of the laminated image pickup device before subjected to various types of image processing, in order to output a specific inference result by an input of the image data obtained by the sensor unit of the laminated image pickup device, it is originally better to use the image (which is inferior in visibility) subjected not to the image processing as training data, but it is difficult to prepare sufficient training data for sufficient learning. Therefore, it is possible to use a larger amount of training data by learning by using an image obtained by other than the sensor unit (which is focused on visibility and aesthetics) as training data. In such a learning method, second image processing for returning the image in the database to the image subjected not to the image processing or sensor data restoration processing for returning the image to pre-image processing data is performed to generate training data and create an inference model. For example, as an output example of inference, information on the limited image acquisition region (priority region) in the sensor unit may be outputted, or an image position and coordinates in a specific object in the image data obtained by the sensor may be outputted.

The image recording unit 133 is configured by a recording medium (not illustrated) such as a hard disk or a memory medium, and classifies and records a plurality of images according to a type of objects included in the images. In the example of FIG. 11, the image recording unit 133 stores a still image group 133a, a movie group 133b, and a tag 133c. The still image group 133a records a plurality of still images, the movie group 133b records a plurality of movies, and the tag 133c records tag information of the image data stored in the still image group 133a and the movie group 133b.

A population creation unit 123 of the learning apparatus 120 records the image from the image pickup apparatus 100, the movie transmitted from the DB apparatus 130, and each of frame image of the movie in a population recording unit 123a. The images recorded in the population recording unit 123a include a moving body.

The learning apparatus 120 includes an input/output setting unit 124. The input/output setting unit 124 sets input data used for learning and contents of output that should be obtained as a result of inference. In the present embodiment, the input/output setting unit 124 sets, according to the inputted frame image, the contents of output such that a priority region candidate region including the moving body of the next frame image is outputted.

An input/output modeling unit 125 determines a network design so that the expected output can be obtained by a large amount of training data, and generates inference model information that is setting information. In other words, the learning apparatus 120 performs the same learning as in FIG. 9 to obtain inference model information for constructing the inference model 72a.

In this way, it is possible to provide a learning method of causing the inference model, in which the image obtained by the sensor unit (pixel array 102b) of the laminated image pickup device is inputted to the inference unit (inference engine 72) provided in the laminated image pickup device (image pickup device 102) and the information on the limited image acquisition region (priority region) in the all effective pixel regions of the sensor unit is outputted, to learn using the image obtained by other than the sensor unit as training data. The inference in the inference unit may perform an output other than the region designation and the frame rate switching. For example, it may be an inference model for detecting a type of the object or an inference model for determining the quality of the object. Further, it may be an inference model for inferring a database in which the photographed image is recorded. As a result, it is possible to immediately use the image pickup result as a candidate for training data or select a database suitable for someone to view. The result of inference for making a judgement on privacy or copyright may be reflected to enhance the security at the time of recording. In addition to the conversion into the training data, an inference may be performed to designate the type of the training data or the learning apparatus 120, and the inference result may be recorded as metadata in the metadata recording region 106b.

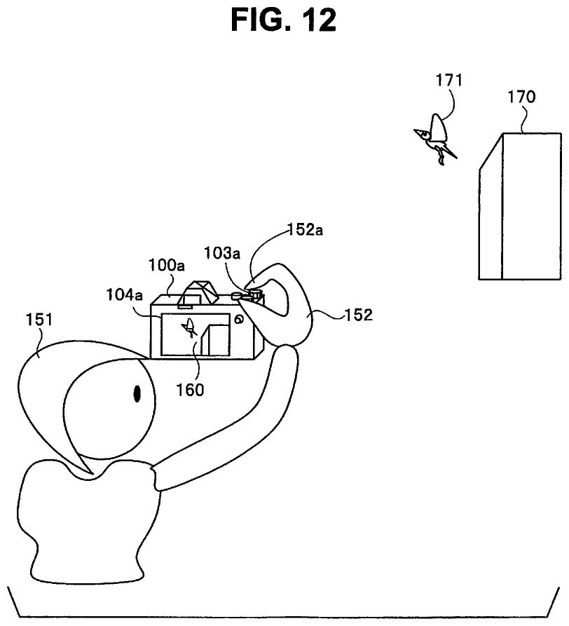

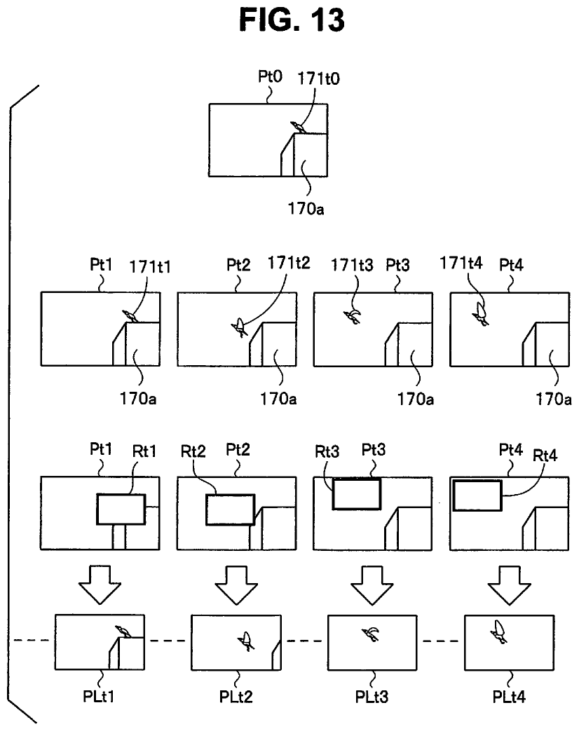

An operation of the embodiment configured as described above will be described below with reference to explanatory diagrams of FIGS. 12 and 13. FIG. 12 is a diagram illustrating a state of photographing by the image pickup apparatus 100, and FIG. 13 is a diagram illustrating a photographing result.

Now, it is assumed that a photographer 151 performs the photographing illustrated in FIG. 12. FIG. 12 illustrates an example in which a bird 171 flies up from a building 170 as an object. The photographer 151 grips a photographing device body 100a with a right hand 152 and presses a release switch 103a on an upper surface of the device body 100a with a forefinger 152a to perform photographing. In FIG. 12, a display screen 104a of a display unit 104 is provided on a back surface of the photographing device body 100a. A picked-up image 160 is displayed in live view on the display screen 104a.

FIG. 13 illustrates the picked-up image in the example of FIG. 12. An image Pt0 in FIG. 13 indicates an image picked up by the image pickup device 102 at a predetermined timing t0. In addition, images Pt1 to Pt4 indicate picked-up images at consecutive timings t0 to t4 at predetermined intervals. The image Pt0 is an image indicating a state in which the bird 171 is stopped on the roof of the building 170, and includes an image 170a of the building 170 and an image 171t0 of the bird 171 at time t0.

The images Pt1 to Pt4 are images when the picked-up images are obtained at the normal frame rate by reading from all effective pixel regions of the pixel array 102b from time t1 to time t4. A visual field range of the photographer 151 is not changed, the position and size of the image 170a of the building 170 are not changed on the images Pt1 to Pt4, and the background image is not changed. On the other hand, the bird 171 flies up from time t1 to time t4, and the image of the bird 171 changes in order of images 171t1 to 171t4.

In the present embodiment, when the photographer 151 focuses on the moving bird 171 to perform photographing, the photographer 151 instructs a high-speed photographing mode in which pixel signals are read from the priority region at a high-speed frame rate. Frames Rt1 to Rt4 in the images Pt1 to Pt4 in FIG. 13 indicate priority region candidate regions in the high-speed photographing mode.

When the image Pt0 is stored in the DRAM 102c in the high-speed photographing mode, the inference engine 72 estimates a position in the picked-up image of the bird 171 at the next timing of the image Pt0 by the inference using inference model 72a, and obtains a priority region candidate region including the position. The next timing of the image Pt0 is earlier than the timing t1 and is a timing corresponding to the normal frame rate and the high-speed frame rate.

The region designation portion 102d sets a priority region based on the priority region candidate region at the time of reading from the pixel array 102b after the next timing. Further, the frame rate switching portion 102e sets a high-speed frame rate based on the effective pixel region and the priority region of the pixel array 102b. Further, the region designation portion 102d changes the priority region based on the detection result of the motion of the bird 171.

The images Pt1 to Pt4 in FIG. 13 indicate priority regions Rt1 to Rt4 at timings t1 to t4 by a rectangular frame. In other words, from the timing after the timing t0, only the pixel signal of the pixel in the priority region is read at the high-speed frame rate, and the pixel signal is stored in the DRAM 102c. Images PLt1 to PLt4 in FIG. 13 indicate picked-up images corresponding to the priority regions Rt1 to Rt4 at the timings t1 to t4. These picked-up images are mainly the images of the bird 171 picked up at a high-speed frame rate.

The recording control portion 101c records the image Pt0 and the images PLt1 to PLt4 in the image data recording region 106a, and records information indicating a correspondence relation between the image Pt0, the images PLt1 to PLt4, and the photographing time in the metadata recording region 106b.

In this way, the photographer 151 can take a photograph focusing on the bird 171 without performing a complicated operation. The image of the priority region is acquired at the high-speed frame rate, and the motion of the bird 171 can be clearly observed from the image.

The photographer 151 can update the inference model 72a used for estimating the priority region. Based on the operation of the photographer 151, the control unit 101 accesses the learning apparatus 120, and acquires inference model information used for constructing the inference model 72a desired by the photographer 151. The inference model information is transferred to the image pickup device 102, and the inference model updating portion 102f updates the inference model 72a with the inference model information. Thus, it is possible to construct the inference model according to the type of the moving object and the background state desired by the photographer 151.

As described above, according to the present embodiment, the same effects as the effects of the respective embodiments can be obtained. According to the present embodiment, it is possible to update the inference model for inferring the priority region, and to improve the estimation accuracy of the priority region for the object desired by the user.

In the embodiments described above, the digital camera is used as an image pickup device, but the camera may be a digital single-lens reflex camera, a compact digital camera, a video camera, a movie camera, and further a camera incorporated in a portable information terminal (PDA: personal digital assistant) such as a cellular phone or a smartphone.

Further, the image pickup device may be an industrial or medical optical device such as an endoscope or microscope, and may be a surveillance camera, an in-vehicle camera, a stationary camera, and for example, a camera attached to a television receiver or a personal computer. For example, when the image pickup device is applied to the medical field, it is possible to clearly pick up the state of moving microorganisms at high speed. The image pickup device can be used to grasp the whole on a screen with a wide angle of view and to acquire images with a faster response within a narrow angle of view. An example of performing such switching at the speed of motion of the target object has been described, but control may be performed such that an image is picked up at a high speed when a specific region is found. It may be considered to be an application for a high-speed image pickup of an important part. In such a case, the priority region may be not a large motion part but a region to be observed so as not to overlook a slight change. In addition, the priority region may be an ambush region so as not to miss a moment when any image is picked up.

The present invention is not limited to the above embodiments with no modification, and the components may be modified and embodied at the implementation stage without departing from the gist matter of the present invention. Furthermore, various inventions may be formed by properly combining plural components disclosed in the respective embodiments. For example, some components of all the components shown in the embodiments may be deleted. Furthermore, the components over the different embodiments may be appropriately combined.

Note that even when the operation flows in the claims, the description and the drawings are described by using “first”, “next”, and the like, the description does not mean that it is indispensable to execute the operation flows in this order. Furthermore, note that the steps configuring these operation flows can be appropriately omitted insofar as the steps do not affect the essence of the invention.

Among the techniques described here, most of the controls described mainly with reference to the flowcharts can be set by a program, and may be stored in a recording medium or a recording unit. The recording medium and the recording unit may be recorded at the time of product shipment, may be used as a distributed recording medium, or may be downloaded via the Internet.

Furthermore, in the embodiments, the portions described as “units” may be configured by dedicated circuits or combining plural general-purpose circuits, or may be configured by combining a microcomputer which operates according to software programmed in advance as needed, and a processor such as CPU or a sequencer such as an FPGA. Furthermore, a design may be performed such that an external device takes over a part or the whole of the control, and in this case, a wired or wireless communication circuit is interposed. The communication may be performed using Bluetooth, WiFi, or a telephone line, and may be performed using USB. A dedicated circuit, a general-purpose circuit, and a control unit may be integrated and configured as an ASIC.

### [Notes]

### [Note 1]

A learning method including:

detecting a moving object from each of frame images of a movie,

generating, based on a result of the detection, training data obtained by adding, to a predetermined frame image, information of a region including a position of the moving object in a frame image next to the predetermined frame image as an annotation,

learning by giving the training data to a neural network (neural network), and

for an inputted image, obtaining an inference model in which a region including a position of the moving object in the image inputted at a next timing of the inputted image is outputted, as an inference result, together with information on reliability.

### [Note 2]

The learning method according to Note 1, wherein a position of the region including the position of the moving object according to the detection result of the moving object is corrected according to a frame rate.

### [Note 3]

An image pickup method including:

detecting a region from an inputted image using the inference model acquired by the learning method according to Note 1, and

reading only an image part corresponding to the region at a frame rate higher than a normal frame rate.

What is claimed is:

1. A laminated image pickup device comprising:
a sensor including a plurality of pixels configured on a sensor substrate and configured to continuously acquire image data at a predetermined frame rate; and
a processor, wherein
the processor is provided on a substrate other than the sensor substrate, and is configured to
perform, based on the image data, region judgement processing of obtaining a priority region including some pixels of the plurality of pixels, and
obtain outputs of the some pixels included in the priority region at a higher frame rate than the predetermined frame rate.

2. The laminated image pickup device according to claim 1, wherein
the priority region is a rectangular region having a predetermined size.

3. The laminated image pickup device according to claim 2, wherein
the higher frame rate is determined according to a size of the rectangular region.

4. The laminated image pickup device according to claim 1, comprising:
a memory configured to temporarily store image data based on outputs of the plurality of pixels, wherein
the processor sets, as the priority region, a region including an image part of a moving object in the image data temporarily stored in the memory.

5. The laminated image pickup device according to claim 4, wherein
the processor moves the priority region based on a motion of the moving object.

6. The laminated image pickup device according to claim 4, wherein
the processor includes an inference engine using an inference model to which the image data temporarily stored in the memory is inputted to infer the region including the image part of the moving object in the inputted image data.

7. The laminated image pickup device according to claim 6, wherein
the inference model is obtained, based on a detection result of positions of the moving object included in each of frame images in a movie, by learning using training data obtained by adding, to a predetermined frame image, information of a region including a position of the moving object in a frame image next to the predetermined frame image as an annotation.

8. The laminated image pickup device according to claim 1, comprising:
a memory configured to temporarily store a plurality of pieces of image data based on outputs of the plurality of pixels, wherein
the processor obtains the priority region based on a difference between the plurality of pieces of image data temporarily stored in the memory.

9. The laminated image pickup device according to claim 8, wherein
the processor sets a background judgement region for judging a background region and a change judgement region for judging a change region in the plurality of pieces of image data temporarily stored in the memory, and determines a priority region based on the change region, based on a change in the image of the background judgement region and a change in the image of the change judgement region based on a result of the difference.

10. The laminated image pickup device according to claim 9, wherein
the processor divides the change judgement region into a plurality of division regions, judges the change region for each of the division regions, and determines the priority region based on the change region.

11. An image pickup apparatus comprising:
the laminated image pickup device according to claim 1; and
a controller configured to control the laminated image pickup device.

12. An image pickup apparatus comprising:
the laminated image pickup device according to claim 6; and
a controller configured to control the laminated image pickup device, wherein
the processor updates the inference model.

13. An image pickup method comprising:
continuously acquiring image data at a predetermined frame rate with a sensor provided on a laminated sensor and including a plurality of pixels;
obtaining, in a circuit on a different layer from the sensor, a priority region including some pixels of the plurality of pixels, based on the image data; and
obtaining outputs of the some pixels included in the priority region at a higher frame rate than the predetermined frame rate.

14. The image pickup method according to claim 13, wherein
the priority region is a rectangular region having a predetermined size.

15. The image pickup method according to claim 14, wherein
the higher frame rate is determined according to a size of the rectangular region.

16. The image pickup method according to claim 13, comprising:
setting a region including an image part of a moving object in the image data, as the priority region.

17. The image pickup method according to claim 16, comprising:
moving the priority region based on a motion of the moving object.

18. The image pickup method according to claim 16, comprising:
obtaining the priority region using an inference model configured to infer the region including the image part of the moving object in the image data.

19. The image pickup method according to claim 18, wherein
the inference model is obtained, based on a detection result of positions of the moving object included in each of frame images in a movie, by learning using training data obtained by adding, to a predetermined frame image, information of a region including a position of the moving object in a frame image next to the predetermined frame image as an annotation.

20. A non-transitory computer-readable recording medium recorded with an image pickup program, the image pickup program causing a computer to execute procedures of:
continuously acquiring image data at a predetermined frame rate with a sensor provided on a laminated sensor and including a plurality of pixels;
obtaining, in a circuit on a different layer from the sensor, a priority region including some pixels of the plurality of pixels, based on the image data; and
obtaining outputs of the some pixels included in the priority region at a higher frame rate than the predetermined frame rate.
